(19) United States
(12) Patent Application Publication
(10) Pub. No.: US 2017/0104038 A1
(43) Pub. Date: Apr. 13, 2017

(54) ORGANIC LIGHT EMITTING DIODE, AND ORGANIC LIGHT EMITTING DIODE DISPLAY INCLUDING THE SAME

(71) Applicant: Samsung Display Co., Ltd., Yongin-si (KR)

(72) Inventors: Chang-Min LEE, Suwon-si (KR); Beom Joon KIM, Seoul (KR); Hyun Ju CHOI, Seoul (KR)

(21) Appl. No.: 15/232,383

(22) Filed: Aug. 9, 2016

(30) Foreign Application Priority Data
Oct. 12, 2015 (KR) 10-2015-0142417

(51) Int. Cl. H01L 27/32; H01L 51/52; H01L 51/50

(52) U.S. Cl. CPC H01L 27/3213; H01L 51/5056; H01L 51/5218; H01L 51/5234; H01L 51/5088; H01L 27/3244; H01L 27/3218; H01L 27/3216; H01L 2251/558

(57) ABSTRACT

An organic light emitting element including a first electrode; an auxiliary layer disposed on the first electrode; a yellow emission layer disposed on the auxiliary layer; and a second electrode disposed on the yellow emission layer, wherein a distance between the first electrode and the yellow emission layer is within one among a first range of 20 nanometers to 30 nanometers, a second range of 170 nanometers to 220 nanometers, and a third range of 280 nanometers to 380 nanometers.

### CROSS-REFERENCE TO RELATED APPLICATION[S]

This application claims priority from and the benefit of Korean Patent Application No. 10-2015-0142417, filed on Oct. 12, 2015, which is hereby incorporated by reference for all purposes as if fully set forth herein.

### BACKGROUND

Field

Exemplary embodiments relate to an organic light emitting element and an organic light emitting diode display including the same.

Discussion of the Background

Recent trends toward lightweight and thin personal computers and televisions sets is also require lightweight and thin display devices, and flat panel displays, such as a liquid crystal display (LCD) satisfying such requirements, are being substituted for conventional cathode ray tubes (CRTs). However, because the LCD is a passive display device, an additional back-light as a light source is needed, and LCDs inherently have various design disadvantages compared with CRTs, such as a slow response time and a narrow viewing angle.

As a display device capable of overcoming the aforementioned limitations, an organic light emitting device, which is a self-emitting type of display element, having advantages of a wide viewing angle, excellent contrast, and a fast response time, has attracted significant attention.

The organic light emitting diode display includes an organic light emitting element, the organic light emitting element includes two electrodes and an emission layer positioned between the two electrodes, and one of the two electrodes injects holes and the other one of the two electrodes injects electrons into the light emitting layer. The injected electrons and holes are combined to form excitons, and the excitons emit light as discharge energy.

In an organic light emitting diode display, studies have been conducted in an effort to improve color reproducibility. However, high power consumption has typically been required to increase color reproducibility in conventional organic light emitting diode displays.

The above information disclosed in this Background section is only for enhancement of understanding of the background of the inventive concept, and, therefore, it may contain information that does not form the prior art that is already known in this country to a person of ordinary skill in the art.

### SUMMARY

Exemplary embodiments provide an organic light emitting element that effectively emits yellow light, and an organic light emitting diode display emitting light of four colors, such as red, green, blue, and yellow.

Additional aspects will be set forth in the detailed description which follows, and, in part, will be apparent from the disclosure, or may be learned by practice of the inventive concept.

An exemplary embodiment discloses an organic light emitting element including a first electrode; an auxiliary layer disposed on the first electrode; a yellow emission layer disposed on the auxiliary layer; and a second electrode disposed on the yellow emission layer. A distance between the first electrode and the yellow emission layer is within one among a first range of 20 nanometers to 30 nanometers, a second range of 170 nanometers to 220 nanometers, and a third range of 280 nanometers to 380 nanometers.

The first electrode may be a reflecting electrode and the second electrode may be a transparent electrode.

The first electrode may be an anode and the second electrode may be a cathode.

The auxiliary layer may include a hole transport layer.

The auxiliary layer may further include a hole injecting layer positioned between the hole transport layer and the first electrode.

When the distance between the first electrode and the yellow emission layer is in the first range, the distance between the first electrode and the second electrode may be in the range of 90 nanometers to 120 nanometers.

When the distance between the first electrode and the yellow emission layer is in the second range, the distance between the first electrode and the second electrode may be in the range of 240 nanometers to 290 nanometers.

When the distance between the first electrode and the yellow emission layer is in the third range, the distance between the first electrode and the second electrode may be in the range of 380 nanometers to 430 nanometers.

A spectrum peak of a light emitted from an organic light emitting element may be in a range of 540 nanometers to 580 nanometers.

An x-coordinate of a color coordinate of the light emitted from the organic light emitting element may be in a range of 0.36 to 0.46, and a y-coordinate is in a range of 0.53 to 0.63.

An electron auxiliary layer positioned between the yellow emission layer and the second electrode may be further included.

The thickness of the electron auxiliary layer may be in a range of 20 nanometers to 50 nanometers.

An exemplary embodiment also discloses an organic light emitting diode display including a plurality of transistors disposed on a substrate; and a plurality of organic light emitting elements connected to the plurality of transistors. At least one of the organic light emitting elements is configured to emit yellow light, and the organic light emitting element configured to emit yellow light includes a first electrode, an auxiliary layer disposed on the first electrode, a yellow emission layer disposed on the auxiliary layer, and a second electrode disposed on the yellow emission layer, and a distance between the first electrode and the yellow emission layer is within one among a first range of 20 nanometers to 30 nanometers, a second range of 170 nanometers to 220 nanometers, and a third range of 280 nanometers to 380 nanometers. The first electrode may be a reflecting electrode and the second electrode may be a transparent electrode.

The first electrode may be an anode and the second electrode may be a cathode.

When the distance between the first electrode and the yellow emission layer is in the first range, the distance between the first electrode and the second electrode may be in the range of 90 nanometers to 120 nanometers.

When the distance between the first electrode and the yellow emission layer is in the second range, the distance between the first electrode and the second electrode may be in the range of 240 nanometers to 290 nanometers.

When the distance between the first electrode and the yellow emission layer is in the third range, the distance between the first electrode and the second electrode may be in the range of 380 nanometers to 430 nanometers.

The auxiliary layer may include a hole transport layer.

The plurality of organic light emitting elements may respectively emit red, green, blue, and yellow, and the organic light emitting elements emitting red, green, blue, and yellow may be arranged in a stripe shape in which the same colors are disposed in the same column, or a shape in which a four color quadrangle pattern made of upper red-green pixels and lower blue-yellow pixels is disposed to be vertically crossed to the adjacent quadrangle pattern, or a shape in which the pixel emitting each color is disposed in a rhombus shape, and the pixel of one rhombus shape is enclosed by eight different pixels, but does not contact another pixel of the rhombus shape of the same color.

As described above, the organic light emitting element according to the present exemplary embodiment may emit yellow having high efficiency, and the organic light emitting diode display according to an exemplary embodiment of the present invention may improve color reproducibility while reducing power consumption. The foregoing general description and the following detailed description are exemplary and explanatory and are intended to provide further explanation of the claimed subject matter.

### BRIEF DESCRIPTION OF THE DRAWINGS

The accompanying drawings, which are included to provide a further understanding of the inventive concept, and are incorporated in and constitute a part of this specification, illustrate exemplary embodiments of the inventive concept, and, together with the description, serve to explain principles of the inventive concept.

FIG. 1 is a cross-sectional view of an organic light emitting element according to an exemplary embodiment of the present invention.

FIG. 2 is a cross-sectional view of an organic light emitting element according to an exemplary embodiment of the present invention.

FIG. 3 is a cross-sectional view of an organic light emitting element according to an exemplary embodiment of the present invention.

FIG. 4 is a graph showing change of efficiency of an x-coordinate and a y-coordinate depending on a light traveling distance.

FIG. 5 is a layout view of an organic light emitting diode display according to an exemplary embodiment of the present invention.

FIG. 6 is a cross-sectional view of the organic light emitting diode display of FIG. 5 taken along line VI-VI′.

FIG. 7 is a cross-sectional view of the organic light emitting diode display of FIG. 5 taken along line VII-VII′.

FIG. 8 is a graph showing efficiency according to a color coordinate shift of red, blue, and green.

FIG. 9, FIG. 10, and FIG. 11 are views of various arrangements of red, green, blue, and yellow pixels in an organic light emitting diode display according to an exemplary embodiment of the present invention.

### DETAILED DESCRIPTION OF THE ILLUSTRATED EMBODIMENTS

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

In the accompanying figures, the size and relative sizes of layers, films, panels, regions, etc., may be exaggerated for clarity and descriptive purposes. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. For the purposes of this disclosure, “at least one of X, Y, and Z” and “at least one selected from the group consisting of X, Y, and Z” may be construed as X only, Y only, Z only, or any combination of two or more is of X, Y, and Z, such as, for instance, XYZ, XYY, YZ, and ZZ. Like numbers refer to like elements throughout. As used herein, the term “and/or” includes any and all combinations of one or more of the associated listed items.

Although the terms first, second, etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the present disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” is and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. The regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

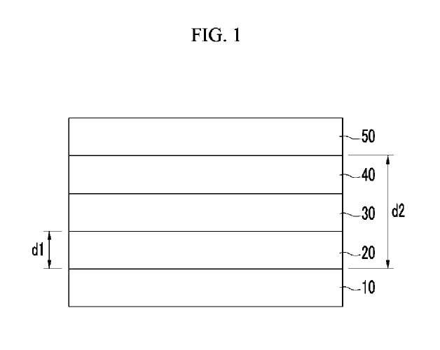

FIG. 1 is a cross-sectional view of an organic light emitting element according to an exemplary embodiment of the present invention. Referring to FIG. 1, the organic light is emitting element according to an exemplary embodiment of the present invention includes a first electrode 10, a hole transferring layer 20 disposed on the first electrode, an emission layer 30 disposed on the hole transferring layer 20, an electron transferring layer 40 disposed on an emission layer 30, and a second electrode 50 disposed on the electron transferring layer 40.

In this case, the first electrode 10 may be an anode, and the second electrode 50 may be a cathode. Also, the first electrode 10 may be a reflecting electrode, and the second electrode 50 may be a transparent electrode.

As will be described in detail later, the emission layer 30 of the organic light emitting element according to an exemplary embodiment of the present invention emits yellow light. In this description, a distance between the first electrode 10 and the emission layer 30 is referred to as a first distance d1, and the distance between the first electrode 10 and the second electrode 50 is referred to as a second distance d2. In the organic light emitting element according to an exemplary embodiment of the present invention, the first distance d1 may be in a first range of 20 nanometers (nm) to 30 nanometers (nm), a second range of 170 nanometers (nm) to 220 nanometers (nm), or a third range of 280 nanometers (nm) to 380 nanometers (nm). Also, each second distance d2 may respectively be from 90 nanometers (nm) to 120 nanometers (nm), from 240 nanometers (nm) to 290 nanometers (nm), or from 380 nanometers (nm) to 430 nanometers (nm).

In this description, the first distance d1 between the first electrode 10 and the emission layer 30, as shown in FIG. 1, includes the distance measured from the upper surface of the first electrode 10 to the lower surface of the emission layer 30, but does not include the thickness of the first electrode 10 or the emission layer 30.

Likewise, in this description, the second distance d2 between the first electrode 10 is and the second electrode 50, as shown in FIG. 1, includes the distance measured from the upper surface of the first electrode 10 to the lower surface of the second electrode 50, but does not include the thickness of the first electrode 10 or the second electrode 50.

The case in which the first distance d1 is from 20 nm to 30 nm and the second distance d2 is from 90 nm to 120 nm is referred to as a first mode; the case in which the first distance d1 is from 170 nm to 220 nm and the second distance d2 is from 240 nm to 290 nm is referred to as a second mode; and the case in which the first distance d1 is from 280 nm to 380 nm and the second distance d2 is from 380 nm to 430 nm is referred to as a third mode.

The first mode, the second mode, and the third mode are each a number range that maximizes the efficiency of the organic light emitting element according to an exemplary embodiment of the present invention when emitting a yellow light. This will be described in detail later.

Next, each layer structure of the organic light emitting element according to an exemplary embodiment of the present invention will be described with reference to FIG. 1.

Referring to FIG. 1, the organic light emitting element according to an exemplary embodiment of the present invention includes the first electrode 10, the hole transferring layer 20 disposed on the first electrode, the emission layer 30 disposed on the hole transport layer, the electron transferring layer 40 disposed on the emission layer 30, and the second electrode 50 disposed on the electron transferring layer 40.

The first electrode 10 may be a transparent electrode or a non-transparent electrode. The transparent electrode may be formed of, for example, a conductive oxide, such as indium tin oxide (ITO), indium zinc oxide (IZO), tin oxide (SnO₂), zinc oxide (ZnO), or combinations thereof, or a metal such as aluminum, silver, magnesium with a thin thickness, and the non-transparent electrode may be formed of a metal such as aluminum, silver, or magnesium.

More specifically, the first electrode 10 of the organic light emitting element according to the exemplary embodiment of the present invention may have a structure in which a reflective layer made of silver (Ag), aluminum (Al), chromium (Cr), molybdenum (Mo), tungsten (W), titanium (Ti), gold (Au), palladium (Pd), or an alloy film thereof, and a transparent electrode material, such as ITO, IZO, or ZnO, are layered. That is, the first electrode 10 of the organic light emitting element according to an exemplary embodiment of the present invention may be the reflecting electrode.

The first electrode 10 may be formed using a sputtering method, a vapor phase deposition method, an ion beam deposition method, an electron beam deposition method, or a laser ablation method. In the organic light emitting element according to the present exemplary embodiment, the first electrode 10 may be an anode.

The second electrode 50 may be a transparent electrode. Also, the second electrode 50 may include a material having a small work function for easy electron injection. For example, the material may be a metal, such as magnesium, calcium, sodium, potassium, titanium, indium, yttrium, lithium, gadolinium, aluminum, silver, tin, lead, cesium, barium, and the like, an alloy thereof, or a multi-layered structure material, such as LiF/Al, LiO₂/Al, LiF/Ca, LiF/Al, and BaF₂/Ca, but the present invention is not so limited. In an exemplary embodiment of the present invention, the second electrode 50 may be the reflecting electrode, may include the conductive oxide such as indium tin oxide (ITO), indium zinc oxide (IZO), tin oxide (SnO₂), zinc oxide (ZnO), or combinations thereof, or may be formed of the metal such as aluminum, silver, magnesium with the thin thickness. In the organic light emitting element according to the present exemplary embodiment, the second electrode 50 may be the cathode.

The first electrode 10 and the second electrode 50 may be formed to have two or more layers, if necessary.

The emission layer 30 of the organic light emitting element according to an exemplary embodiment of the present invention emits yellow light. That is, the emission layer 30 according to an exemplary embodiment of the present invention may include a dopant configured to emit yellow light.

The emission layer 30 may be manufactured by additionally doping a light emitting dopant into an emission layer host. In this case, the content of the light emitting dopant may vary depending on a material forming an emission layer, but generally, the content of the light emitting dopant may be in the range of about 3 to about 10 parts by weight based on 100 parts by weight of the material forming the emission layer (total weight of the host and the dopant). In this case, the dopant may be the dopant configured to emit yellow light.

A material of a fluorescent light emitting host may include tris(8-hydroxy-quinolinato)aluminum (Alq3), 9,10-di(naphth-2-yl)anthracene (AND), 3-tert-butyl-9,10-di(naphth-2-yl)anthracene (TBADN), 4,4′-bis(2,2-diphenyl-ethene-1-yl)-4,4′-dimethylphenyl (DPVBi), 4,4′-bisbis(2,2-diphenyl-ethene-1-yl)-4,4′-methylphenyl (p-DMDPVBi), tert(9,9-diarylfluorene)s (TDAF), 2-(9,9′-spirobifluorene-2-yl)-9,9′-spirobifluorene (BSDF), 2,7-bis(9,9′-spirobifluorene-2-yl)-9,9′-spirobifluorene (TSDF), bis(9,9-diarylfluorene)s (BDAF), 4,4′-bis(2,2-diphenyl-ethene-1-yl)-4,4′-di-(tert-butyl)phenyl (p-TDPVBi), or the like, and a phosphorescent host may have a material including 1,3-bis(carbazole-9-yl)benzene (mCP), 1,3,5-tris(carbazole-9-yl)benzene (tCP), 4,4′,4″-tris(carbazole-9-yl)triphenylamine (TcTa), 4,4′-bis(carbazole-9-yl)biphenyl (CBP), 4,4′-bis(9-carbazolyl)-2,2′-dimethyl-biphenyl (CBDP), 4,4′-bis(carbazole-9-yl)-9,9-dimethyl-fluorene (DMFL-CBP), 4,4′-bis(carbazole -9-yl)-9,9-bis(9-phenyl-9H-carbazole)fluorene (FL-4CBP), 4,4′-bis(carbazole -9-yl)-9,9-di-tolyl-fluorene (DPFL-CBP), 9,9-bis(9-phenyl-9H-carbazole)fluorene (FL-2CBP), or the like.

The dopant may include 8-Hydroxyquinoline and complexes of similar derivatives, benzazole derivatives, however, it is not limited thereto.

That is, in the emission layer 30 of the organic light emitting element according to an exemplary embodiment of the present invention, the yellow dopant may be added to the emission layer host. In this case, a center wavelength of the yellow light emitted from the emission layer 30 may be formed to be between about 540 nm to 580 nm. The center wavelength of the yellow light emitted from the emission layer 30 may be formed to be between 550 nm to 560 nm.

In this case, in a color coordinate of the emitted light, an x-coordinate may be positioned between 0.36 to 0.46, and a y-coordinate may be positioned between 0.53 to 0.63. This center wavelength and color coordinate are each a number indicating a high visual characteristic (human visual response). The yellow light having this center wavelength and color coordinate is emitted with high efficiency in the display device according to an exemplary embodiment of the present invention.

The hole transferring layer 20 is positioned between the first electrode 10 and the emission layer 30. The hole transferring layer 20 may be formed of a carbazole derivative, such as N-phenylcarbazole, polyvinylcarbazole, and an typical amine derivative having an aromatic condensed ring such as N,N′-bis(3-methylphenyl)-N,N′-diphenyl-[1,1-biphenyl]-4,4′-diamine (TPD) and N,N′-di(naphthalene-1-yl)-N,N′-diphenyl benzidine (NPD).

The electron transferring layer 40 is positioned between the second electrode 50 and the emission layer 30. The electron transferring layer 40 may include at least one compound is selected from a quinoline derivative, particularly a group including tris(8-hydroxyquinolinato)aluminum (Alq3), 3-(4-biphenyl)-4-phenyl-5-(4-tert-butylphenyl)-1,2,4-triazole (TAZ), (2-methyl-8-quninolinato)-4-phenylphenolate (BAlq), bis(10-hydroxybenzo(h)quinolinato)beryllium (Bebq2), and 4,7-diphenyl-1-10-phenanthroline (BPhen). Also, the compound selected from the above group may be doped with Liq to be used. In this case, the doping concentration may be 50 wt %.

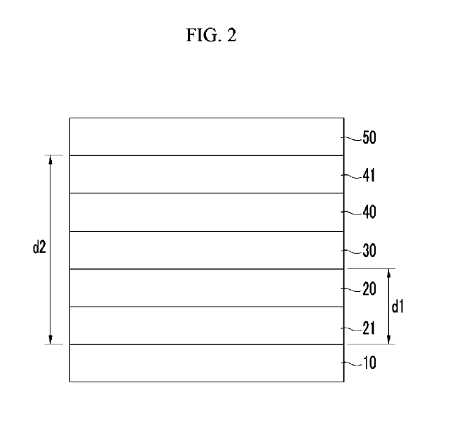

FIG. 2 is a cross-sectional view of an organic light emitting element according to an exemplary embodiment of the present invention.

Referring to FIG. 2, the organic light emitting element according to an exemplary embodiment of the present invention has constituent elements similar to most of those of the display device according to the exemplary embodiment of FIG. 1. However, the organic light emitting element according to the exemplary embodiment of FIG. 2 additionally includes a hole injecting layer 21 disposed between the hole transferring layer 20 and the first electrode 10 and an electron injecting layer 41 disposed between the second electrode 50 and the electron transferring layer 40.

A known hole injection material, such as TCTA, m-MTDATA, m-MTDAPB, Pani/DBSA (Polyaniline/Dodecylbenzene sulfonic acid), which is a soluble conductive polymer, or PEDOT/PSS (Poly(3,4-ethylenedioxythiophene)/Poly(4-styrenesulfonate): poly(3,4-ethylenedioxythiophene)/poly(4-styrenesulfonate)), Pani/CSA (Polyaniline/Camphor sulfonic acid), or PANI/PSS (Polyaniline)/Poly (4-styrenesulfonate)) may be used as the hole injection material 21.

The electron injecting layer 41 may include a random material that is known as a material for forming the electron injection layer, such as LiF, NaCl, CsF, Li₂O, or BaO.

In this case, in the organic light emitting element according to the exemplary embodiment of FIG. 2, the first distance d1 between the first electrode 10 and the emission layer 30 may be substantially the same as the sum of each thickness of the hole transferring layer 20 and the hole injecting layer 21.

Also, in the organic light emitting element according to the exemplary embodiment of FIG. 2, the second distance d2 between the first electrode 10 and the second electrode 50 is substantially the same as the sum of each thickness of the hole transferring layer 20, the hole injecting layer 21, the emission layer 30, the electron transferring layer 40, and the electron injecting layer 41.

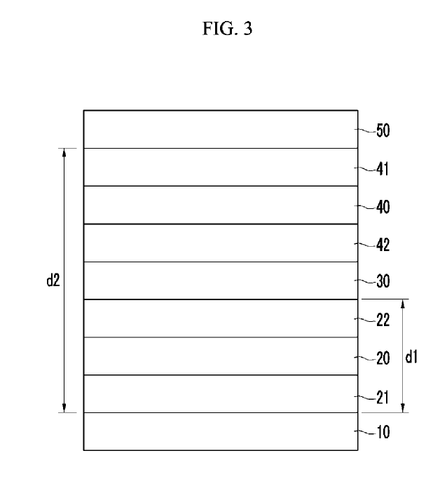

FIG. 3 is a cross-sectional view of an organic light emitting element according to an exemplary embodiment of the present invention. Referring to FIG. 3, the display device according to the exemplary embodiment of FIG. 3 has constituent elements similar to most of those of the display device according to the exemplary embodiment of FIG. 2. However, the display device according to the exemplary embodiment of FIG. 3 includes a yellow middle layer 22 positioned between the hole transferring layer 20 and the emission layer 30 and a buffer layer 42 positioned between the emission layer 30 and the electron transferring layer 40.

The yellow middle layer preferably has a material in which the HOMO energy level difference is not more than 0.3 eV for the hole transport layer for increasing the emission efficiency of the element.

The buffer layer 42 is the material increasing the emission efficiency of the element and functions to smooth an energy band gap between the electron transferring layer40 and the emission layer 30.

In this case, in the organic light emitting element according to the exemplary embodiment of FIG. 3, the first distance d1 between the first electrode 10 and the emission layer 30 may be substantially the same as the sum of each thickness of the yellow middle layer 22, the hole transferring layer 20, and the hole injecting layer 21.

Also, in the organic light emitting element according to the exemplary embodiment of FIG. 3, the second distance d2 between the first electrode 10 and the second electrode 50 is substantially the same as the sum of each thickness of the hole transferring layer 20, the hole injecting layer 21, the yellow middle layer 22, the emission layer 30, the buffer layer 42, the electron transferring layer 40, and the electron injecting layer 41.

In the organic light emitting element according to the exemplary embodiment of FIG. 1 to FIG. 3, a layer layered between the first electrode 10 and the emission layer 30 is referred to as an auxiliary layer. The auxiliary layer may include at least one layer among the hole transferring layer 20, the hole injecting layer 21, and the yellow middle layer 22 according to each exemplary embodiment.

Also, in the organic light emitting element according to the exemplary embodiment of FIG. 1 to FIG. 3, the layer layered between the emission layer 30 and the second electrode 50 is referred to as an electron auxiliary layer. The electron auxiliary layer according to each exemplary embodiment may include at least one layer among the buffer layer 42, the electron transferring layer 40, and the electron injecting layer 41.

As described, in the organic light emitting element according to an exemplary embodiment of the present invention, the first electrode 10 may be made of the reflecting electrode and the second electrode 50 may be made of the transparent electrode. In this case, the first distance d1 from the first electrode 10 to the emission layer 30 may be from 20 nm to 30 nm. In this case, the second distance d2 between the first electrode 10 and the second electrode 50 may be from 90 nm to 120 nm, and this is referred to as the first mode.

Also, the first distance d1 may be from 170 nm to 220 nm, the second distance d2 may be from 240 nm to 290 nm, and this is referred to as the second mode.

Also, the first distance d1 may be from 280 nm to 380 nm, in this case, the second distance d2 may be from 380 nm to 430 nm, and this is referred to as the third mode.

In the organic light emitting element configured to emit yellow light, each of these ranges is a range that maximizes the emission efficiency of the organic light emitting element.

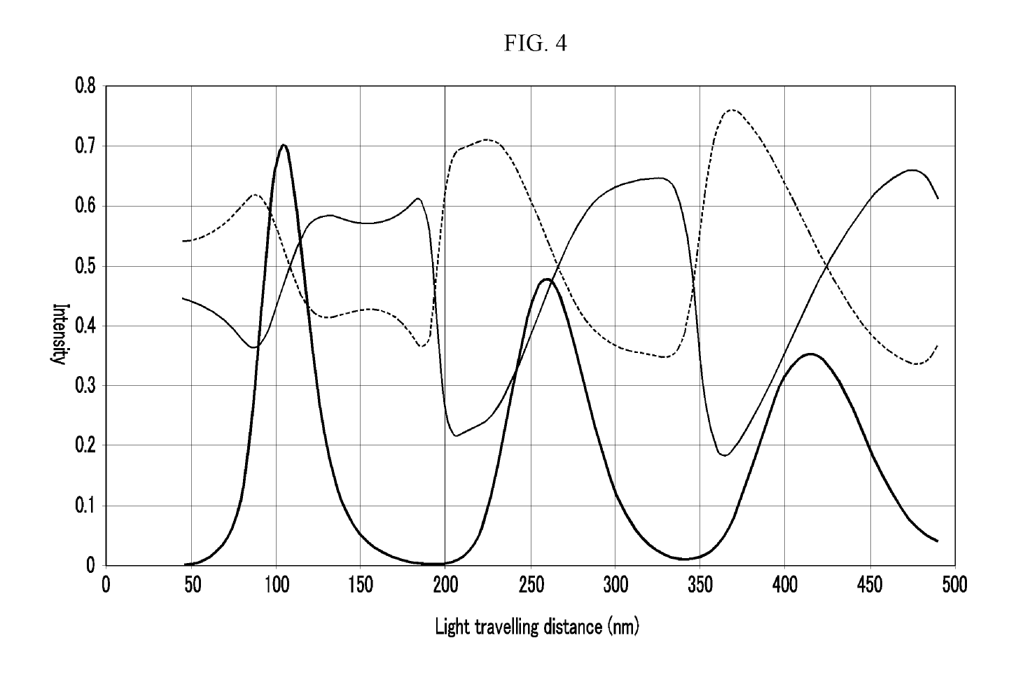

FIG. 4 is a graph showing change of efficiency of an x-coordinate and a y-coordinate depending on a light traveling distance. The horizontal axis of FIG. 4 indicates a light traveling distance (nm) and a left vertical axis indicates an intensity of the emitted light.

Referring to FIG. 4, a peak appears at a region of about 105 nm, at a region of about 265 nm, and at a region of about 415 nm.

The case in which the light path is about 105 nm corresponds to the first mode of the organic light emitting element according to the present exemplary embodiment. Also, the case in which the light path is about 265 nm corresponds to the second mode of the organic light emitting element according to the present exemplary embodiment. In addition, the case in which the light path is about 415 nm corresponds to the third mode of the organic light emitting element according to the present exemplary embodiment.

Accordingly, the organic light emitting element having the layer thickness of the first mode, the second mode, and the third mode according to an exemplary embodiment of the present invention may obtain optimized emission efficiency in the organic light emitting element configured to emit yellow light.

In the organic light emitting element according to the exemplary embodiment of FIG. 1, the thickness of the electron transferring layer 40 may be from 20 nm to 50 nm. In this case, the thickness of the second electrode 50 may be from 5 nm to 20 nm.

In the organic light emitting element according to the exemplary embodiment of FIG. 2, the sum of the thicknesses of the second electrode 50 and the electron injecting layer 41 may be in the range of 5 nm to 20 nm. In this case, the thickness of the electron transferring layer 40 may be in the range of 20 nm to 50 nm. Also, in the organic light emitting element according to the exemplary embodiment of FIG. 2, the sum of the thicknesses of the electron transferring layer 40 and the electron injecting layer 41 may be in the range of 20 nm to 50 nm, and the thickness of the second electrode may be in the range of the 5 nm to 20 nm.

In the organic light emitting element according to the exemplary embodiment of FIG. 3, the sum of the thicknesses of the second electrode 50 and the electron injecting layer 41 may be in the range of 5 nm to 20 nm, and the sum of the thicknesses of the electron transferring layer 40 and the buffer layer 42 may be in the range of 20 nm to 50 nm. Also, in the organic light emitting element according to the exemplary embodiment of FIG. 3, the thickness of the second electrode 50 may be in the range of 5 nm to 20 nm, and the sum of the thicknesses of the electron injecting layer 41, the electron transferring layer 40, and the buffer layer 42 may be in the range of 20 nm to 50 nm.

In the organic light emitting element according to the exemplary embodiment of FIG. 1 to FIG. 3, the first distance d1 from the first electrode 10 to the emission layer 30, and the distance d2 between the first electrode 10 and the second electrode 50, may have the thicknesses of the first mode, the second mode, or the third mode described above.

As described above, the organic light emitting element according to an exemplary embodiment of the present invention has a light path in which the light efficiency is maximized in the organic light emitting element configured to emit yellow light, thereby improving the efficiency of the organic light emitting element configured to emit yellow light.

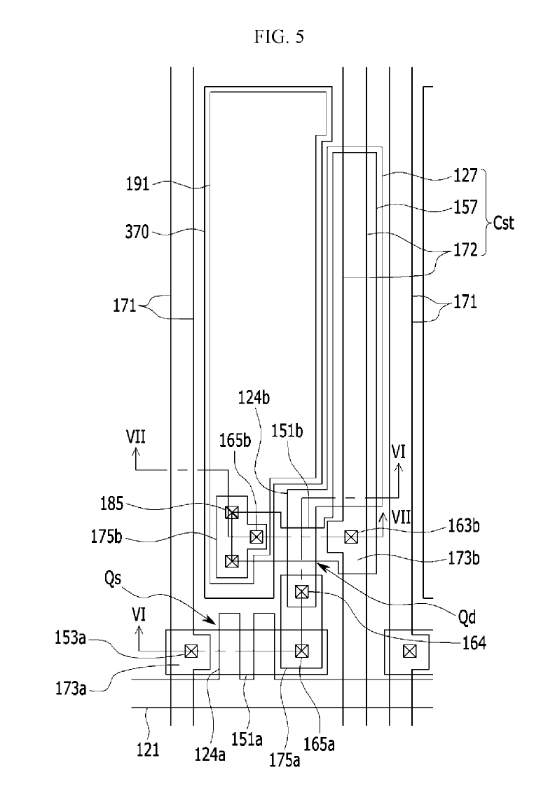

Next, the organic light emitting diode display including the organic light emitting element according to an exemplary embodiment of the present invention will be described with reference to FIG. 5 to FIG. 7.

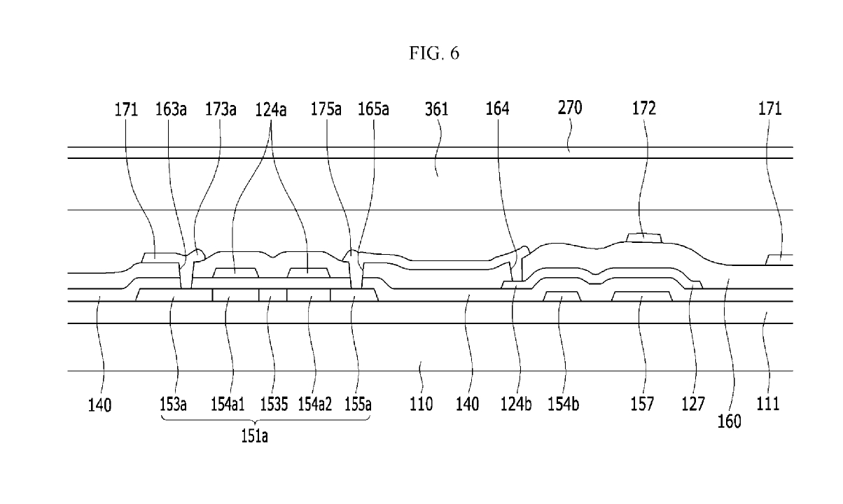

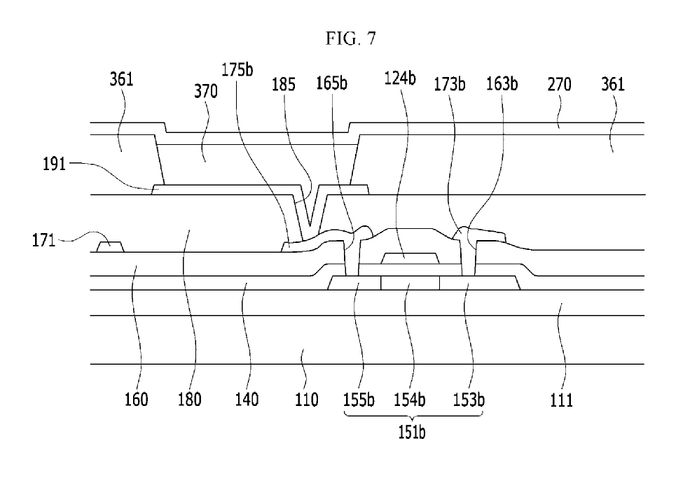

FIG. 5 is a layout view of an organic light emitting diode display according to an exemplary embodiment of the present invention. FIG. 6 is a cross-sectional view of the organic light emitting diode display of FIG. 5 taken along line VI-VI′. FIG. 7 is a cross-sectional view of the organic light emitting diode display of FIG. 5 taken along line VII-VII′.

Referring to FIG. 5 to FIG. 7, a blocking layer 111 made of a silicon oxide or silicon nitride is disposed on a substrate 110 made of transparent glass. The blocking layer 111 may have a dual-layered structure.

A plurality of pairs of first and second semiconductor islands 151a and 151b that are preferably made of polysilicon are formed on the blocking layer 111. The first and second semiconductor islands 151a and 151b respectively include a plurality of extrinsic regions including conductive impurities of an n-type or a p-type, and at least one intrinsic region that does not include conductive impurities.

In the first semiconductor island 151a, the extrinsic region includes first source and drain regions 153a and 155a and an intermediate region 1535, and they are doped with an n-type impurity and separated from each other. The intrinsic region includes a pair of first channel regions 154a1 and 154a2 disposed between the extrinsic regions 153a, 1535, and 155a.

In the second semiconductor island 151b, the extrinsic region includes second source and drain regions 153b and 155b, and they are doped with a p-type impurity and are separated from each other. The intrinsic region includes a second channel region 154b disposed between the second source and drain regions 153b and 155b, and a storage region 157 extending from the second drain region 153b upward.

The extrinsic region further includes lightly doped regions (not shown) disposed between the channel regions 154a1, 154a2, and 154b, and the source and drain regions 153a, 155a, 153b, and 155b. The lightly doped regions may be formed at offset regions that do not include impurities.

Alternatively, the extrinsic regions 153a and 155a of the first semiconductor island 151a may be doped with p-type impurities, and the extrinsic regions 153b and 155b of the second semiconductor island 151b may be doped with n-type impurities. The conductive p-type impurity may be boron (B) or gallium (Ga), and the conductive impurity of the n-type may be phosphorus (P) or arsenic (As).

A gate insulating layer 140 that may be made of a silicon nitride or silicon oxide is disposed on the semiconductor islands 151a and 151b and the blocking layer 111.

A plurality of gate conductors including a plurality of gate lines 121 having a plurality of first control electrodes 124a and a plurality of second control electrodes 124b are formed on the gate insulating layer 140.

The gate lines 121 transmit gate signals and substantially extend in the transverse direction. A first control electrode 124a extends upward from the gate line 121, thereby intersecting the first semiconductor island 151a, and more particularly overlapping the first channel regions 154a1 and 154a2. Each gate line 121 may include an end portion having a large area for contacting another layer or an external driving circuit. When a gate driving circuit (not shown) for generating gate signals is formed directly on the substrate 110, the gate lines 121 may extend and directly connect to the gate driving circuit.

A second control electrode 124b is separated from the gate line 121 and overlaps the second channel region 154b of the second semiconductor island 151b. The second control electrode 124b extends to form a storage electrode 127, and the storage electrode 127 overlaps the storage region 157 of the second semiconductor 151b.

The gate conductors 121 and 124b may be made of an aluminum-based metal of aluminum (Al) or aluminum alloys, a silver-based metal of silver (Ag) or silver alloys, a copper-based metal of copper (Cu) or copper alloys, a molybdenum-based metal of molybdenum (Mo) or molybdenum alloys, chromium (Cr), tantalum (Ta), titanium (Ti), etc. However, the control electrodes 124a and 124b may have a multi-layer structure including two conductive layers (not shown) that have different physical properties from each other. One of the conductive layers may be formed using a metal having low resistivity, such as an aluminum-based metal, a silver-based metal, or a copper-based metal, in order to reduce signal delay or voltage drop. Other conductive layers may be formed using a material having good physical, chemical, and electrical contact characteristics, particularly with indium tin oxide (ITO) and indium zinc oxide (IZO), such as a molybdenum-based metal, chromium, tantalum, titanium, or the like. Examples of the combination may include a lower chromium film and an upper aluminum (alloy) film, and a lower aluminum (alloy) film and an upper molybdenum (alloy) film. However, the gate conductors 121 and 124b may be made of various metals or conductors.

Side surfaces of the gate conductors 121 and 124b are inclined to the surface of the substrate 110, and an inclination angle thereof is preferably about 30° to 80°.

An interlayer insulating layer 160 is disposed on the gate conductors 121 and 124b. The interlayer insulating layer 160 is made of an inorganic insulator, such as a silicon nitride, a silicon oxide, etc., and an organic insulator, or an insulator having a low dielectric ratio. The dielectric constant of the insulator may be less than 4.0, for example, an a-Si:C:O or a-Si:O:F, which is formed through plasma enhanced chemical vapor deposition (PECVD). The interlayer insulating layer 160 may be made of an organic insulator having photosensitivity and may provide a flat surface.

The interlayer insulating layer 160 has a plurality of contact holes 164 exposing the second control electrodes 124b. Also, the interlayer insulating layer 160 and the gate insulating layer 140 have a plurality of contact holes 163a, 163b, 165a, and 165b exposing the source and drain regions 153a, 153b, 155a, and 155b.

A plurality of data conductors including data lines 171, driving voltage lines 172, and first and second output electrodes 175a and 175b are formed on the interlayer insulating layer 160.

The data lines 171 transmit data signals and extend in a longitudinal direction, thereby intersecting the gate lines 121. Each data line 171 includes a first input electrode 173a connected to the first source region 153a through the contact hole 163a, and may include an end portion having a large area for contacting another layer or an external driving circuit. When a data driving circuit (not shown) for generating data signals is formed directly on the substrate 110, the data line 171 may extend and be directly connected to the data driving circuit.

The driving voltage lines 172 transmit a driving voltage and extend in a longitudinal direction, thereby intersecting the gate lines 121. Each driving voltage line 172 includes a plurality of second input electrodes 173b connected to the second source region 153b through the contact holes 163b. The driving voltage line 172 overlaps the storage electrode 127 and they may be connected to each other.

The first output electrode 175a is separated from the data line 171 and the driving voltage line 172. The first output electrode 175a is connected to the first drain region 155a through the contact hole 165a, and to the second control electrode 124b through the contact hole 164.

The second output electrode 175b is separated from the data line 171, the driving voltage line 172, and the first output electrode 175a, and is connected to the second drain region 155b through the contact hole 165b.

The data conductors 171, 172, 175a, and 175b may be made of a refractory metal, such as molybdenum, chromium, tantalum, and titanium, or alloys thereof, and have a multi-layered structure including a refractory metal layer (not shown) and a low resistance conductive layer (not shown). A multi-layered structure includes, for example, a dual layer of a chromium or molybdenum (alloy) lower layer and an aluminum (alloy) upper layer, and a triple-layer of a molybdenum (alloy) lower layer, an aluminum (alloy) middle layer, and a molybdenum (alloy) upper layer. However, the data conductors 171, 172, 175a, and 175b may be made of various other metals or conductors.

Side surfaces of the data conductor 171, 172, 175a, and 175b may also be inclined to the surface of the substrate 110, and an inclination angle thereof may be about 30° to 80°, like the gate conductors 121 and 124b.

A passivation layer 180 is disposed on the data conductors 171, 172, 175a, and 175b. The passivation layer 180 is made of an inorganic material, an organic material, or a low dielectric ratio insulating material.

The passivation layer 180 has a plurality of contact holes 185 exposing the second output electrodes 175b. The passivation layer 180 may have a plurality of contact holes (not shown) exposing the end portions of the data lines 171, and the passivation layer 180 and the interlayer insulating layer 160 may have a plurality of contact holes (not shown) exposing the end portions of the gate lines 121.

A plurality of pixel electrodes 191 are formed on the passivation layer 180. The pixel electrodes 191 are physically and electrically connected to the second output electrodes 175b through the contact holes 185, and may be made of a transparent conductive material such as ITO or IZO, or a reflective conductor such as silver, aluminum, or alloys thereof.

A plurality of contact assistants (not shown) or connecting members (not shown) may be formed on the passivation layer 180 and may be connected to exposed ends of the gate lines 121 and the data lines 171.

Partitions 361 are formed on the passivation layer 180. The partitions 361 define a plurality of openings enclosing edges of the pixel electrodes 191 like a bank, and are made of an organic insulator or an inorganic insulator. The partitions 361 may be made of a photoresist including black pigments, and the partitions 361 function as a light blocking member, thereby simplifying the manufacturing process.

A light emitting element layer 370 is disposed on the pixel electrode 191 and a common electrode 270 is disposed on the light emitting element layer 370. As described above, an organic light emitting element including the pixel electrode 191, the light emitting element layer 370, and the common electrode 270 is made.

That is, the organic light emitting element may have the structure of the first electrode/the hole transport layer/the emission layer/the electron transport layer/the second electrode. In this case, the first electrode may be the anode, and the second electrode may be the cathode. Also, the hole injecting layer positioned between the first electrode and the hole transferring layer and the electron injecting layer positioned between the second electrode and the electron transferring layer may be further included. In addition, the middle layer positioned between the hole transport layer and the emission layer and the buffer layer positioned between the emission layer and the electron transferring layer may be further included.

In this case, the pixel electrode 191 becomes the anode as the hole injection electrode, and the common electrode 270 becomes the cathode as the electron injection electrode. However, the exemplary embodiment of the present invention is not limited thereto, and according to a driving method of the organic light emitting device, the pixel electrode 191 may be a cathode and the common electrode 270 may be an anode. The hole and electron are injected into the organic emission layer 370 from the pixel electrode 191 and the common electrode 270, respectively, and an exciton generated by coupling the injected hole and electron falls from an excited state to a ground state to emit light.

The common electrode 270 is formed on the light emitting element layer 370. The common electrode 270 receives a common voltage, and is made of a reflective metal including calcium (Ca), barium (Ba), magnesium (Mg), aluminum (Al), silver (Ag), and the like, or a transparent conductive material such as ITO or IZO.

In the organic light emitting diode display according to the present exemplary embodiment, the description of the hole transferring layer/the emission layer/the electron transferring layer/the barrier layer configuring the organic light emitting element is the same as described above. Also, the light emitting element layer may further includes the hole injecting layer, the middle layer, the buffer layer, and the electron injecting layer, and the description for each layer is the same as described above.

In the organic light emitting diode display according to an exemplary embodiment of the present invention, the first electrode may be made of the reflective metal and the second electrode may be made of the transparent metal. In the organic light emitting diode display according to an exemplary embodiment of the present invention, the emission layer may be the yellow emission layer. In this case, the first distance d1 from the first electrode to the emission layer may be in the range of 20 nm to 30 nm, and thus the second distance d2 from the first electrode to the second electrode may be in the range of 90 nm to 120 nm. Also, the first distance d1 from the first electrode to the emission layer may be in the range of 170 nm to 220 nm, and the second distance d2 from the first electrode to the second electrode may be in the range of 240 nm to 290 nm. Also, the first distance d1 from the first electrode to the emission layer may be in the range of 280 nm to 380 nm, and the second distance d2 from the first electrode to the second electrode may be in the range of 380 nm to 430 nm.

In the organic light emitting device, the first semiconductor island 151a, the first control electrode 124a connected to the gate line 121, the first input electrode 173a connected to the data line 171, and the first output electrode 175a form the switching thin film transistor Qs, and the channel of the switching thin film transistor Qs is formed on the first channel region 154a1 and 154a2 of the first semiconductor island 151a. The second semiconductor island 151b, the second control electrode 124b connected to the first output electrode 175a, the second input electrode 173b connected to the driving voltage line 172, and the output electrode 175b connected to the pixel electrode form the driving thin film transistor Qd, and the channel of the driving thin film transistor Qd is formed in the second channel region 154b of the second semiconductor island 151b. A pixel electrode 191, an organic light emitting member 370, and the common electrode 270 form an organic light emitting element having the pixel electrode 191 as an anode and the common electrode 270 as a cathode, or vice versa. The storage electrode 127 and the driving voltage line 172, and the storage region 157, which overlap each other, may form a storage capacitor Cst.

The switching thin film transistor Qs transmits a data signal of the data line 171 in response to a gate signal of the gate line 121. When receiving the data signal, the driving thin film transistor Qd flows a current that depends on a voltage difference between the second control electrode 124b and the second input electrode 173b. The voltage difference between the second control electrode 124b and the second input electrode 173b is charged to the storage capacitor Cst and then maintained even after the switching thin film transistor Qs is turned off. The organic light emitting diode displays an image by emitting light, the strength of which varies depending on a current of the driving thin film transistor Qd.

However, the structure of the described organic light emitting diode display is one example, and the organic light emitting element according to an exemplary embodiment of the present invention may be clearly applied to an organic light emitting diode display having a different structure.

The organic light emitting diode display according to the exemplary embodiment is described for the organic light emitting element emitting yellow, however the organic light emitting diode display may emit red, blue, and green depending on the material included in the emission layer. The organic light emitting elements respectively emitting red, blue, green, and yellow are referred to as a red pixel, a blue pixel, a green pixel, and a yellow pixel.

The organic light emitting diode display according to an exemplary embodiment of the present invention includes the red pixel, the green pixel, the blue pixel, and the yellow pixel disposed on the substrate.

The typical organic light emitting diode display includes three color pixels of red, green, and blue, and the various colors including white are displayed through combinations of these colors. However, consumers have recently required improved color reproducibility, and a deep red and a deep green are required in order to implement color that is more realistic. In other words, through the emission of darker red than red (deep red), and darker green than green (deep green), colors more similar to reality may be displayed. However, in the case of emitting deep red and deep green, the efficiency decreases.

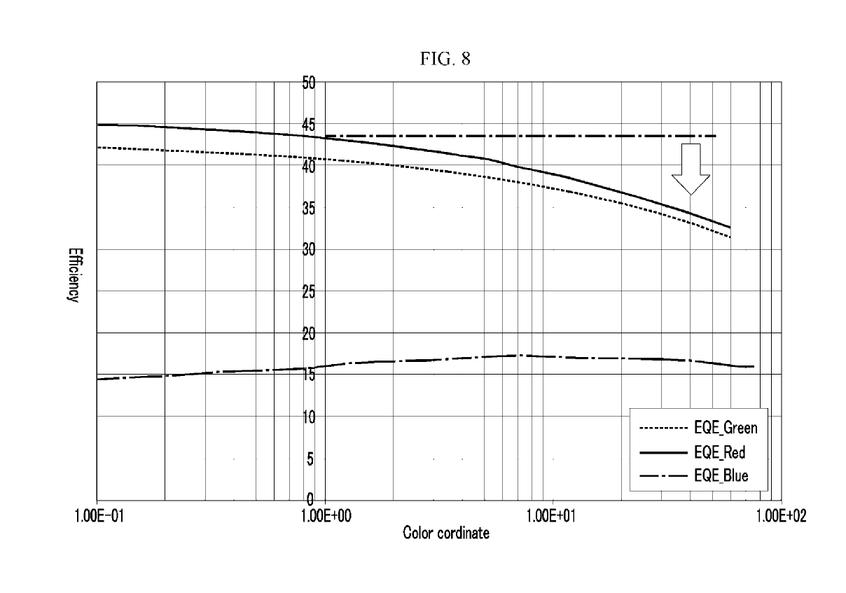

FIG. 8 is a view showing efficiency according to a color coordinate shift of red, blue, and green. The horizontal axis of FIG. 8 indicates color coordinate, and the vertical axis of FIG. 8 indicates efficiency.

Referring to FIG. 8, it may be observed that the efficiency decreases for the color coordinate as it shifts to the right for the red color EQE_Red (moving from red to deep red). Likewise, it may be observed that the efficiency decreases for color coordinate as it shifts to the right for the green color EQE_Green (moving from green to deep green).

Accordingly, when displaying the deep green or the deep red in the conventional organic light emitting diode display having three pixels of red, green, and blue, a relatively large amount of power is consumed.

However, the organic light emitting diode display according to an exemplary embodiment of the present invention has four pixels of red, green, blue, and yellow.

As such, because the four colors of red, green, blue, and yellow are used when displaying white light, power consumption may be reduced compared to displaying white by using only three colors. For this reason, the one yellow pixel has high visibility such that the highest light efficiency may be obtained with the same quantum efficiency. Also, when generally displaying yellow light with three pixels, the red pixel and the green pixel are used, however, only the yellow pixel is used for displaying yellow light in the four-color structure.

Accordingly, because the organic light emitting diode display according to an exemplary embodiment of the present invention has a lower power consumption compared to the conventional three-pixel structure, the power consumption required when emitting deep red and deep green may be compensated for. Accordingly, the entire power consumption efficiency of the organic light emitting diode display may be improved compared to the conventional organic light emitting diode display, even though deep red and deep green are emitted.

Also, in the display device according to an exemplary embodiment of the present invention, because the thickness is optimized for the pixel displaying yellow light to have maximum emission efficiency, high purity yellow light may be emitted and the entire color reproducibility of the organic light emitting diode display may be improved.

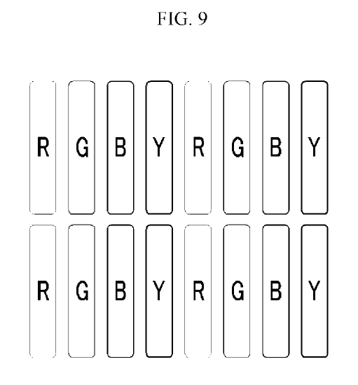

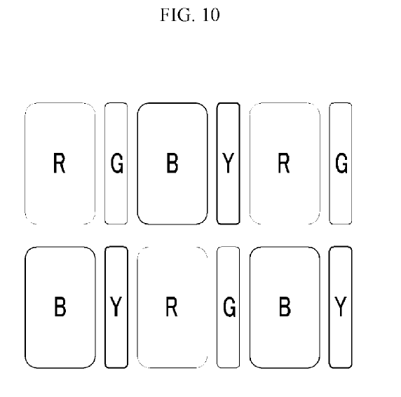

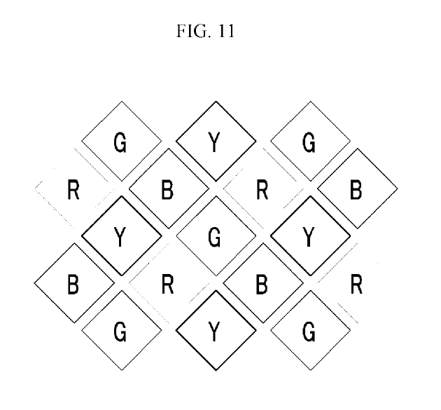

FIG. 9 to FIG. 11 are views of various arrangements of red, green, blue, and yellow pixels in an organic light emitting diode display according to an exemplary embodiment of the present invention.

Referring to FIG. 9, in the organic light emitting diode display according to an exemplary embodiment of the present invention, the red, green, blue, and yellow pixels may be arranged in a stripe structure in which the same colors are disposed in the same column.

In addition, referring to FIG. 10, in the organic light emitting diode display according to an exemplary embodiment of the present invention, the red, green, blue, and yellow pixels may be arranged in a pentile structure in which a quadrangle repletion pattern of upper red-green pixels and lower blue-yellow pixel are disposed to cross. That is, the four color quadrangle patterns including the upper red-green pixels and the lower blue-yellow pixels may be arranged to vertically change for the adjacent quadrangle pattern.

Further, referring to FIG. 11, the organic light emitting diode display according to an exemplary embodiment of the present invention may have a pentile-diamond structure in which the pixels of red, green, blue, and yellow may be arranged in a diamond. That is, the pixels emitting each color are arranged in a rhombus shape, the pixel of one rhombus shape is enclosed by eight different pixels, but does not contact another pixel of the same color of the rhombus shape.

As described above, the organic light emitting element according to the present exemplary embodiment may emit yellow light having high efficiency, and the organic light emitting diode display according to an exemplary embodiment of the present invention may improve color reproducibility while reducing power consumption.

Although certain exemplary embodiments and implementations have been described herein, other embodiments and modifications will be apparent from this description. Accordingly, the inventive concept is not limited to such embodiments, but rather to the broader scope of the presented claims and various obvious modifications and equivalent arrangements.

What is claimed is:

1. An organic light emitting element comprising:
a first electrode;
an auxiliary layer disposed on the first electrode;
a yellow emission layer disposed on the auxiliary layer; and
a second electrode disposed on the yellow emission layer,
wherein a distance between the first electrode and the yellow emission layer is within one among a first range of 20 nanometers to 30 nanometers, a second range of 170 nanometers to 220 nanometers, and a third range of 280 nanometers to 380 nanometers.

2. The organic light emitting element of claim 1, wherein the first electrode comprises a reflecting electrode, and the second electrode comprises a transparent electrode.

3. The organic light emitting element of claim 1, wherein the first electrode comprises an anode, and the second electrode comprises a cathode.

4. The organic light emitting element of claim 1, wherein the auxiliary layer comprises a hole transport layer.

5. The organic light emitting element of claim 4, wherein the auxiliary layer further comprises a hole injecting layer disposed between the hole transport layer and the first electrode.

6. The organic light emitting element of claim 1, wherein, when a distance between the first electrode and the yellow emission layer is in the first range, a distance between the first electrode and the second electrode is in a range of 90 nanometers to 120 nanometers.

7. The organic light emitting element of claim 1, wherein, when a distance between the first electrode and the yellow emission layer is in the second range, a distance between the first electrode and the second electrode is in a range of 240 nanometers to 290 nanometers.

8. The organic light emitting element of claim 1, wherein, when a distance between the first electrode and the yellow emission layer is in the third range, a distance between the first electrode and the second electrode is in a range of 380 nanometers to 430 nanometers.

9. The organic light emitting element of claim 1, wherein a spectrum peak of light emitted from the organic light emitting element is in a range of 540 nanometers to 580 nanometers.

10. The organic light emitting element of claim 1, wherein an x-coordinate of a color coordinate of the light emitted from the organic light emitting element is in a range of 0.36 to 0.46, and a y-coordinate is in a range of 0.53 to 0.63.

11. The organic light emitting element of claim 1, further comprising an electron auxiliary layer disposed between the yellow emission layer and the second electrode.

12. The organic light emitting element of claim 11, wherein a thickness of the electron auxiliary layer is in a range of 20 nanometers to 50 nanometers.

13. An organic light emitting diode display comprising:
a plurality of transistors arranged on a substrate; and
a plurality of organic light emitting elements connected to the plurality of transistors,
wherein:
at least one of the organic light emitting elements is configured to emit yellow light;
the organic light emitting element configured to emit yellow light comprises:
a first electrode;
an auxiliary layer disposed on the first electrode;
a yellow emission layer disposed on the auxiliary layer; and
a second electrode disposed on the yellow emission layer; and
a distance between the first electrode and the yellow emission layer is within one among a first range of 20 nanometers to 30 nanometers, a second range of 170 nanometers to 220 nanometers, and a third range of 280 nanometers to 380 nanometers.

14. The organic light emitting diode display of claim 13, wherein the first electrode comprises a reflecting electrode, and the second electrode comprises a transparent electrode.

15. The organic light emitting diode display of claim 13, wherein the first electrode comprises an anode, and the second electrode comprises a cathode.

16. The organic light emitting diode display of claim 13, wherein, when a distance between the first electrode and the yellow emission layer is the first range, a distance between the first electrode and the second electrode is in a range of 90 nanometers to 120 nanometers.

17. The organic light emitting diode display of claim 13, wherein, when a distance between the first electrode and the yellow emission layer is in the second range, a distance between the first electrode and the second electrode is in a range of 240 nanometers to 290 nanometers.

18. The organic light emitting diode display of claim 13, wherein, when a distance between the first electrode and the yellow emission layer is in the third range, a distance between the first electrode and the second electrode is in a range of 380 nanometers to 430 nanometers.

19. The organic light emitting diode display of claim 13, wherein the auxiliary layer comprises a hole transport layer.

20. The organic light emitting diode display of claim 13, wherein:
the organic light emitting elements are configured to respectively emit red light, green light, blue light, and yellow light; and
the organic light emitting elements configured to emit red, green, blue, and yellow are arranged:
in a stripe shape in which the same colors are disposed in the same column, or
a shape in which a four color quadrangle pattern made of upper red-green pixels and lower blue-yellow pixels is disposed to vertically cross the adjacent quadrangle pattern, or
a shape in which the pixel configured to emit each color is disposed in a rhombus shape, and the pixel of one rhombus shape is enclosed by eight different pixels but does not contact another pixel of the rhombus shape of the same color.
